(19) United States
(12) Patent Application Publication
(10) Pub. No.: US 2023/0240006 A1
(43) Pub. Date: Jul. 27, 2023

(54) ELECTRONIC DEVICE HAVING SUBMERSION DETECTION CIRCUIT, OPERATING METHOD THEREOF, AND STEER-BY-WIRE STEERING DEVICE INCLUDING THE SAME

(71) Applicant: HL MANDO CORPORATION, Pyeongtaek-si (KR)

(72) Inventors: Su Min LEE, Siheung-si Gyeonggi-do (KR); Kyu Yeong JE, Yongin-si Gyeonggi-do (KR)

(73) Assignee: HL MANDO CORPORATION, Pyeongtaek-sii-do (KR)

(21) Appl. No.: 18/099,438

(22) Filed: Jan. 20, 2023

(30) Foreign Application Priority Data
Jan. 27, 2022 (KR) 10-2022-0012430
Jan. 27, 2022 (KR) 10-2022-0012438
Jul. 6, 2022 (KR) 10-2022-0083319

(51) Int. Cl. H05K 1/02; H02H 5/08; H05K 5/00; H02H 1/00; H05K 1/14; G01R 31/52; G01R 19/00; B62D 5/00

(52) U.S. Cl. CPC H05K 1/0296; H02H 5/083; H05K 5/0026; H02H 1/0007; H05K 1/142; G01R 31/52; G01R 19/0038; B62D 5/005; H05K 2201/1034; H05K 2201/10545

(57) ABSTRACT

An electronic device includes a circuit board having a signal detection terminal disposed on a first surface thereof and a ground terminal disposed on a second surface thereof and extending vertically so that the first surface and the second surface face each other in a horizontal direction, a monitoring terminal connected with the signal detection terminal, and a microcontroller unit (MCU) determining whether there is submersion by monitoring a voltage at the monitoring terminal. According to the present embodiments, it is possible to prevent hypersensitivity-induced misdetection due to condensation and dew. It is also possible to stepwise respond to submersion and determine whether the monitoring circuit normally operates to precisely detect submersion.

### CROSS-REFERENCE TO RELATED APPLICATION

The present application claims the benefit of priority to Korean Patent Application Nos. 10-2022-0012438, 10-2022-0012430, and 10-2022-0083319, filed on Jan. 27, 2022, Jan. 27, 2022, and Jul. 6, 2022, respectively, which are hereby incorporated by reference for all purposes as if fully set forth herein.

### TECHNICAL FIELD

The embodiments of the present disclosure relate to an electronic device having a submersion detection circuit and a method for operating the same, which may prevent hypersensitivity-induced misdetection due to condensation or dew in monitoring whether the electronic device is submerged.

The present embodiments of the present disclosure relate to an electronic device having a submersion detection circuit and a method for operating the same, which may stepwise respond to submersion and determine whether the monitoring circuit normally operates to precisely detect submersion.

### BACKGROUND

A conventional monitoring circuit for determining whether an electronic device is submerged includes a constant power source terminal and a monitoring terminal pulled down to the ground. In this case, the constant power source terminal and the monitoring terminal are disposed adjacent to each other on the circuit board to determine that there is submersion from a short circuit between the constant power source terminal and the monitoring terminal due to the submersion.

However, in the conventional structure, the constant power source terminal and the monitoring terminal are disposed on the same surface on the circuit board, so that the constant power source terminal and the monitoring terminal may be short-circuited even by dew or condensation due to temperature or humidity. In other words, condensation or dew may lead to erroneous detection of submersion despite absence of submersion, deteriorating the accuracy of detection.

Further, the monitoring terminal remains pulled down to the ground to determine whether there is submersion so that it is impossible to distinguish between a short circuit due to failure in the monitoring circuit and a short circuit due to submersion.

### SUMMARY

The embodiments of the present disclosure have been conceived in the foregoing background and may prevent hypersensitivity-induced misdetection due to condensation and dew. There may be provided an electronic device having a submersion detection circuit and a method for operating the same, which may stepwise respond to submersion and determine whether the monitoring circuit normally operates to precisely detect submersion.

According to one exemplary embodiment of the present disclosure, there may be provided an electronic device including a circuit board having a signal detection terminal disposed on a first surface thereof and a ground terminal disposed on a second surface thereof and extending vertically so that the first surface and the second surface face each other in a horizontal direction, a monitoring terminal connected with the signal detection terminal and a microcontroller unit (MCU) determining whether there is submersion by monitoring a voltage at the monitoring terminal.

According to one exemplary embodiment of the present disclosure, there may be provided an electronic device comprising a circuit board having a signal detection terminal disposed on a first surface thereof and extending vertically so that the first surface and a second surface face each other in a horizontal direction, a housing receiving the circuit board and connected to a ground, a monitoring terminal connected with the signal detection terminal and an MCU determining whether there is submersion by monitoring a voltage at the monitoring terminal.

According to one exemplary embodiment of the present disclosure, there may be provided a method for operating an electronic device including a circuit board having a signal detection terminal disposed on a first surface thereof and a ground terminal disposed on a second surface thereof and extending vertically so that the first surface and the second surface face each other in a horizontal direction, a monitoring terminal connected with the signal detection terminal, and an MCU connected with the monitoring terminal, comprising monitoring a voltage at the monitoring terminal, comparing the voltage at the monitoring terminal with a normal state voltage, and determining whether there is submersion from the comparison.

According to one exemplary embodiment of the present disclosure, there may be provided a steer-by-wire steering device including an electronic device comprising a circuit board having a signal detection terminal disposed on a first surface thereof and a ground terminal disposed on a second surface thereof and extending vertically so that the first surface and the second surface face each other in a horizontal direction, a monitoring terminal connected with the signal detection terminal and an MCU determining whether there is submersion by monitoring a voltage at the monitoring terminal. According to one exemplary embodiment of the present disclosure, there may be provided a steer-by-wire steering device including an electronic device comprising a circuit board having a signal detection terminal disposed on a first surface thereof and extending vertically so that the first surface and a second surface face each other in a horizontal direction, a housing receiving the circuit board and connected to a ground, a monitoring terminal connected with the signal detection terminal and an MCU determining whether there is submersion by monitoring a voltage at the monitoring terminal.

According to the exemplary embodiments of the present disclosure, it is possible to prevent hypersensitivity-induced misdetection due to condensation and dew. It is also possible to stepwise respond to submersion and determine whether the monitoring circuit normally operates to precisely detect submersion.

### DESCRIPTION OF DRAWINGS

The above and other objects, features, and advantages of the disclosure will be more clearly understood from the following detailed description, taken in conjunction with the accompanying drawings, in which:

FIG. 1 is a circuit diagram illustrating an electronic device according to one exemplary embodiment of the present disclosure;

FIGS. 2A, 2B, and 2C are a view schematically illustrating a state of an electronic device according to various exemplary embodiments of the present disclosure;

FIGS. 3A and 3B are a side view illustrating a portion of a steer-by-wire steering device including an electronic device according to various exemplary embodiments of the present disclosure;

FIGS. 4A, 4B, 4C, and 4D are a side view illustrating a portion of an electronic device according to various exemplary embodiments of the present disclosure;

FIGS. 5A and 5B are a front view illustrating a portion of an electronic device according to one exemplary embodiment of the present disclosure;

FIGS. 6A, 6B, 6C, and 6D are a side view illustrating a portion of an electronic device according to various exemplary embodiments of the present disclosure;

FIG. 7 is a circuit diagram illustrating an electronic device according to one exemplary embodiment of the present disclosure;

FIG. 8 is a circuit diagram illustrating an electronic device according to one exemplary embodiment of the present disclosure;

FIG. 9 is a circuit diagram illustrating an electronic device according to one exemplary embodiment of the present disclosure;

FIG. 10 is a circuit diagram illustrating an electronic device according to one exemplary embodiment of the present disclosure;

FIG. 11 is a circuit diagram illustrating an electronic device according to one exemplary embodiment of the present disclosure; and

FIG. 12A is a circuit diagram illustrating an electronic device according to one exemplary embodiment of the present disclosure, and FIG. 12B is a side view illustrating a portion of a steer-by-wire steering device including an electronic device according to one exemplary embodiment of the present disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

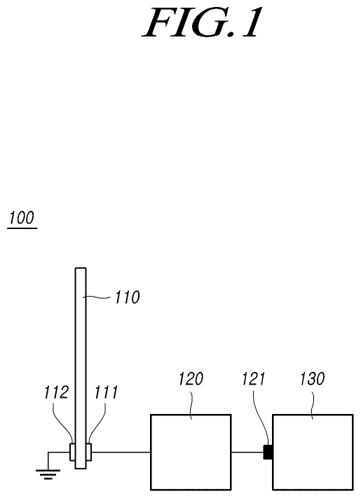

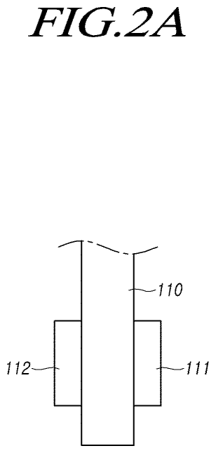

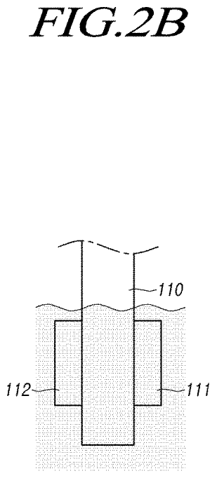

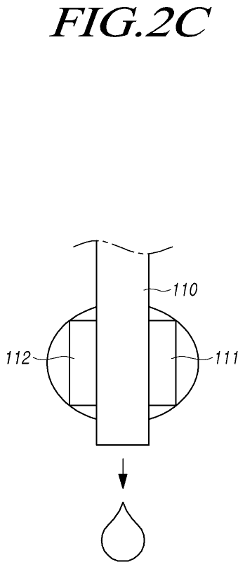

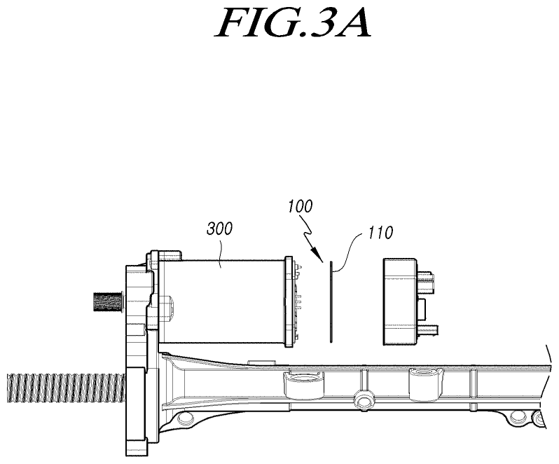

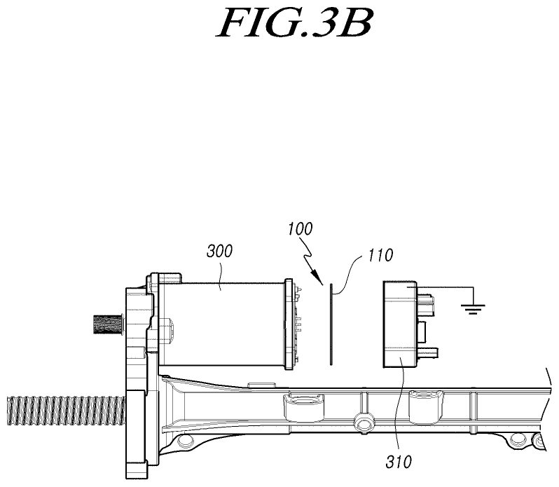

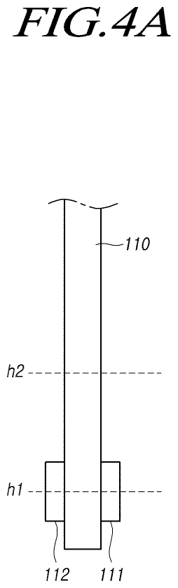

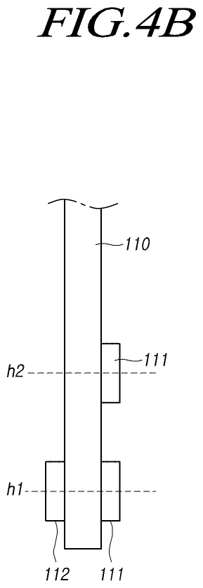

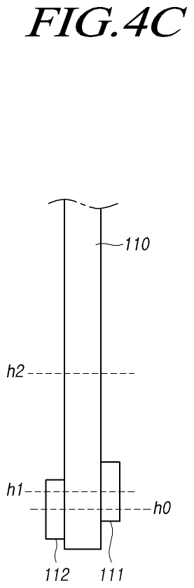

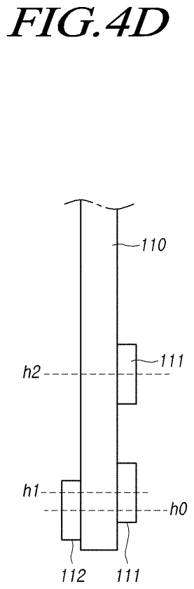

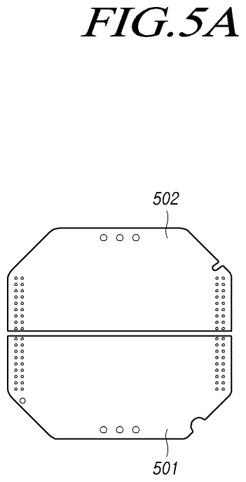

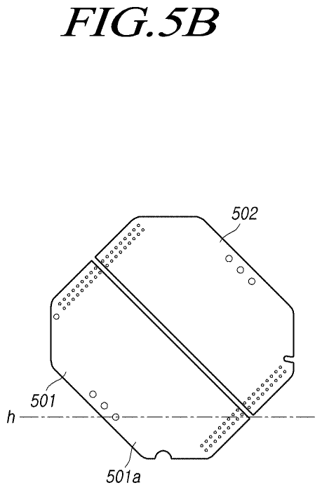

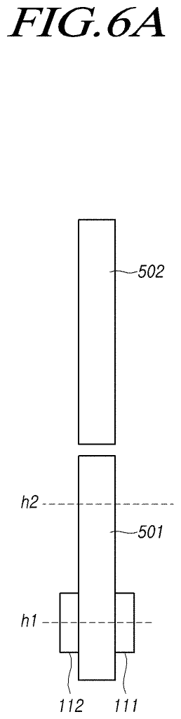

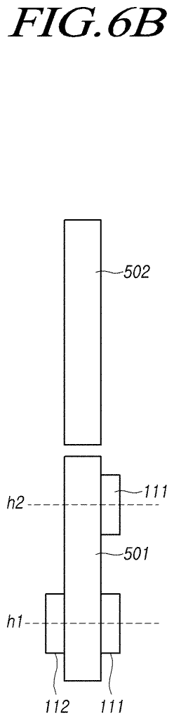

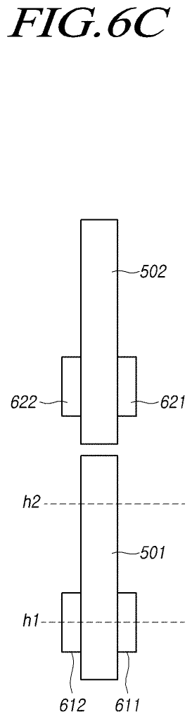

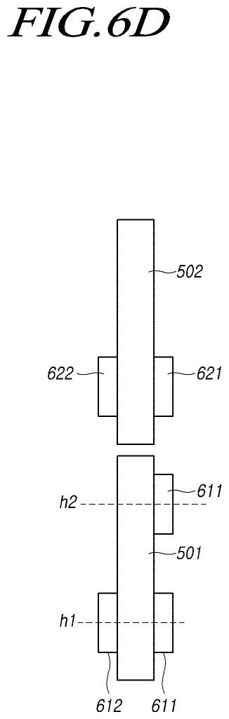

FIG. 1 is a circuit diagram illustrating an electronic device according to one exemplary embodiment of the present disclosure. FIGS. 2A to 2C are a view schematically illustrating a state of an electronic device according to various exemplary embodiments of the present disclosure. FIGS. 3A and 3B are a side view illustrating a portion of a steer-by-wire steering device including an electronic device according to various exemplary embodiments of the present disclosure. FIGS. 4A to 4D are a side view illustrating a portion of an electronic device according to various exemplary embodiments of the present disclosure. FIGS. 5A and 5B are a front view illustrating a portion of an electronic device according to various exemplary embodiments of the present disclosure. FIGS. 6A to 6D are a side view illustrating a portion of an electronic device according to various exemplary embodiments of the present disclosure.

First, various exemplary embodiments of the present disclosure are illustrated in FIGS. 1 to 6.

According to one exemplary embodiment of the present disclosure, in an aspect, there may be provided an electronic device 100 comprising a circuit board 110 having a signal detection terminal 111 disposed on a first surface thereof and a ground terminal 112 disposed on a second surface thereof and extending vertically so that the first surface and the second surface face each other in a horizontal direction, a monitoring terminal 121 connected with the signal detection terminal 111 and a microcontroller unit (MCU) 130 determining whether there is submersion by monitoring a voltage at the monitoring terminal 121.

The MCU 130 of the electronic device 100 according to an exemplary embodiment of the present disclosure may be a processor (e.g., computer, microprocessor, CPU, ASIC, circuitry, logic circuits, etc.). The MCU 130 may be implemented by a non-transitory memory storing, e.g., a program(s), software instructions reproducing algorithms, etc., which, when executed, performs various functions described hereinafter, and a processor configured to execute the program(s), software instructions reproducing algorithms, etc. Herein, the memory and the processor may be implemented as separate semiconductor circuits. Alternatively, the memory and the processor may be implemented as a single integrated semiconductor circuit. The processor may embody one or more processor(s).

Referring to FIG. 1, a monitoring circuit 120 is positioned between the signal detection terminal 111 and the MCU 130, receives the voltage at the signal detection terminal 111, and outputs the voltage at the monitoring terminal 121. The monitoring circuit 120 may include a first filter circuit for removing noise or stabilizing a signal from the input from the signal detection terminal 111 and a second filter circuit for removing noise or stabilizing a signal from the output to the monitoring terminal 121.

The MCU 130 receives the voltage at the monitoring terminal 121 and determines whether there is submersion. When the input voltage at the monitoring terminal 121 drops, the MCU 130 determines that a short circuit has occurred between the signal detection terminal 111 and the ground terminal 112 due to submersion. When the drop of the input voltage at the monitoring terminal 121 relative to the normal state maintains a specific threshold range or more for a specific threshold time or longer, the MCU 130 may detect the voltage drop as a voltage drop due to a resistive short circuit and determine that the circuit board 110 has submerged.

Upon determining that the circuit board 110 has submerged, the MCU 130 may cut off the power supply to the circuit board 110 and perform a subsequent measure, such as outputting a warning message to a driver.

As described below, the monitoring circuit 120 is configured to be able to prevent misdetection of a short circuit due to the failure in the monitoring circuit 120 as submersion. The MCU 130 monitors the voltage at the monitoring terminal 121 and identifies the normal operation of the monitoring circuit 120 from the fact that the input voltage at the monitoring terminal 121 is maintained in the normal state. When a short circuit occurs due to a failure in the monitoring circuit 120, the voltage at the monitoring terminal 121 drops to ground, so that a short circuit due to a failure in the monitoring circuit 120 and a resistive short circuit due to submersion may be distinguished.

Further, as described below, when a plurality of signal detection terminals 111 are disposed on the circuit board 110, each signal detection terminal 111 may be connected to a respective monitoring circuit 120 and monitoring terminal 121. In other words, each monitoring circuit 120 is connected with its corresponding signal detection terminal 111 and monitoring terminal 121 to receive the voltage at the signal detection terminal 111 and output a voltage to the monitoring terminal 121. The MCU 130 receives the voltage at each monitoring terminal 121 and determines whether the corresponding signal detection terminal 111 submerges. As the plurality of signal detection terminals 111 are positioned at different vertical heights on the circuit board 110, it is possible to detect the degree of submersion.

The signal detection terminal 111 and ground terminal 112 for detecting submersion in the electronic device 100 according to one exemplary embodiment of the present disclosure are disposed on the opposite surfaces of the circuit board 110. Accordingly, no short circuit occurs between the signal detection terminal 111 and the ground terminal 112 due to condensation or dew on one surface or the other surface of the circuit board 110.

The circuit board 110 is disposed so that the signal detection terminal 111 and the ground terminal 112 face each other in the horizontal direction.

Accordingly, the water droplets generated on the surface of the circuit board 110 due to condensation or dew, rather than submersion of the circuit board, may fall under the influence of gravity. In this case, since no short circuit occurs between the signal detection terminal 111 and the ground terminal 112, it is possible to prevent misdetection of submersion of the electronic device due to condensation or dew.

As described below, the signal detection terminal 111 and the ground terminal 112 may be disposed at a lower end of the circuit board 110 to be able to quickly detect submersion. Even if the signal detection terminal 111 and the ground terminal 112 are positioned on the edge side of the circuit board 110, the water droplets generated on the circuit board 110 are dropped by gravity before they grow enough to short the signal detection terminal 111 and ground terminal 112 on the edge side due to the thickness of the circuit board 110 (refer to FIG. 2C).

In other words, condensation and dew falls by gravity before growing to a size sufficient to short-circuit the signal detection terminal 111 and the ground terminal 112 respectively positioned on one side and the other side of the circuit board 110. Accordingly, it is possible to prevent hypersensitivity-induced misdetection in which condensation or dew is mistakenly identified as a submersion, thereby enhancing accuracy of detection.

Referring to FIGS. 2A to 2C, a normal state, a submerged state, and a dew/condensation state of the electronic device 100 according to various exemplary embodiments of the present disclosure are described.

FIG. 2A illustrates an example of the normal state. In the normal state, since the signal detection terminal 111 and the ground terminal 112 are open, the voltage at the monitoring terminal 121 represents the normal state voltage, and the MCU 130 does not determine that there is submersion.

FIG. 2B illustrates an example of the submerged state. In the submerged state, the signal detection terminal 111 and the ground terminal 112 are short-circuited due to the submersion, resulting in a resistive short circuit. The MCU 130 detects submersion from the voltage drop at the monitoring terminal 121. For example, when the normal state voltage is 5V, the MCU 130 may detect the submergence when the voltage at the monitoring terminal 121 drops to 4V or less.

FIG. 2C illustrates an example of a state in which water droplets are generated on the surface of the circuit board 110 due to condensation or dew. As the signal detection terminal 111 and the ground terminal 112 are disposed on the opposite surfaces of the circuit board 110, water droplets generated on one surface or the other surface of the circuit board 110 may not short the signal detection terminal 111 and the ground terminal 112. Even if the signal detection terminal 111 and the ground terminal 112 are positioned at the lower end which is the edge side of the circuit board 110 as shown in the drawings, the water droplets generated on the circuit board 110 are dropped by gravity before they grow enough to short the signal detection terminal 111 and ground terminal 112 on the two opposite surfaces due to the thickness of the circuit board 110. Accordingly, it is possible to prevent hypersensitivity-induced misdetection in which condensation or dew is mistaken for submersion of the circuit board.

Referring to FIGS. 3A and 3B, the electronic device 100 according to various exemplary embodiments of the present disclosure may be applied to a vehicle steering system. A steer-by-wire steering device including the electronic device 100 according to the present embodiments may be provided. More specifically, a steer-by-wire steering device including the electronic device 100 according to the embodiment shown in FIG. 1 may be provided.

According to an embodiment, the electronic device 100 may be a device for controlling a motor 300 for sliding a rack bar to assist the driver in steering in a power-assisted steering system. According to an embodiment, the electronic device 100 may be a device for controlling the motor 300 for sliding the rack bar in response to the driver's steering in a steer-by-wire system.

In the power-assisted steering system and the steer-by-wire system, the motor 300 for sliding the rack bar is coupled to a rack housing and positioned at a bottom of a vehicle, so that the electronic device directly coupled to the motor 300 to control the motor 300 may have a relatively high probability of submersion. Accordingly, the electronic device 100 according to the present embodiments can make it possible to detect submersion with high accuracy.

In such a power-assisted steering system or a steer-by-wire system, a vent hole or a breather for controlling the internal pressure of an electronic device is formed in a housing of the electronic device to control the motor 300. Water cannot pass through the vent hole or breather, but moisture may do, frequently causing dew condensation inside the electronic device. However, the electronic device 100 according to the present embodiments can make it possible to suppress the occurrence of a short circuit due to condensation caused by moisture introduced into the electronic device.

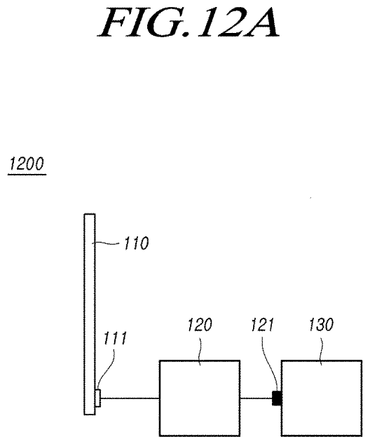

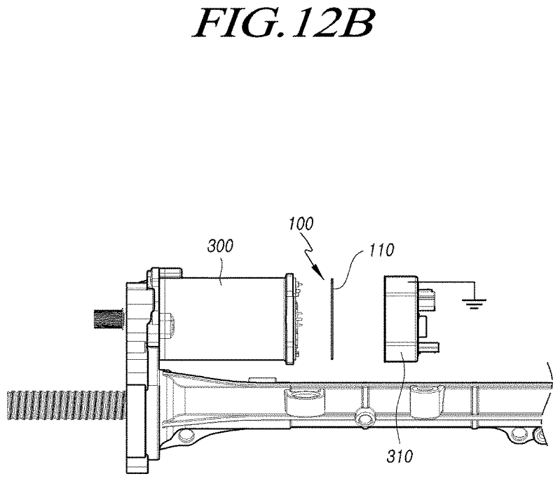

Such features above are illustrated below in FIGS. 12A and 12B. FIG. 12A is a circuit diagram illustrating an electronic device according to one exemplary embodiment of the present disclosure, and FIG. 12B is a side view illustrating a portion of a steer-by-wire steering device including an electronic device according to one exemplary embodiment of the present disclosure. A steer-by-wire steering device including the electronic device 1200 according to the present embodiments may be provided. Referring to FIG. 12B, a steer-by-wire steering device including the electronic device 1200 according to the embodiment shown in FIG. 12A may be provided.

According to one exemplary embodiment of the present disclosure, there may be provided an electronic device 1200 comprising a circuit board 110 having a signal detection terminal 111 disposed on a first surface thereof and extending vertically so that the first surface and a second surface face each other in a horizontal direction, a housing 310 receiving the circuit board 110 and connected to a ground, a monitoring terminal 121 connected with the signal detection terminal 111 and an MCU 130 determining whether there is submersion by monitoring a voltage at the monitoring terminal 121. The same reference numerals are used to denote the same elements as those in the embodiment shown in FIG. 1, and the description may be simplified while focusing primarily on the differences.

As shown in FIG. 12A, the circuit board 110 of the electronic device 1200 according to the present embodiments may include a signal detection terminal 111 on one side thereof. Referring to FIG. 12B, the electronic device 1200 according to the present embodiments further may include a housing 310 receiving the circuit board 110 and connected to a ground and may thus detect submersion from a resistive short circuit occurring between the signal detection terminal 111 and the housing 310 during submersion. Since no ground terminal is disposed on the other side surface of the circuit board 110, it is possible to implement a smaller circuit.

When submersion occurs, water fills up inside the housing 310, causing a resistive short circuit between the housing 310 and the signal detection terminal 111, and the MCU 130 detects submersion from the voltage drop due to the resistive short circuit.

As compared with the embodiment shown in FIG. 1, it is possible to detect submersion even without a ground terminal on the circuit board 110, rendering it possible to relatively downsize the electronic device. Connecting the housing 310 to the ground, rather than providing a ground terminal on the other side surface of the circuit board 110, may prevent water droplets generated on the surface of the circuit board 110 from contacting the housing 310 by the space between the surface of the circuit board 110 and the housing 310. Accordingly, it is possible to prevent hypersensitivity-induced misdetection due to condensation or dew.

According to an embodiment, the signal detection terminal 111 and the ground terminal 112 may be positioned at a lower end of the circuit board 110.

Referring to FIG. 4A, the circuit board 110 is disposed in a vertical direction so that the signal detection terminal 111 and the ground terminal 112 may face each other in the horizontal direction, and the signal detection terminal 111 and the ground terminal 112 may be positioned at lower edges, on one side surface and the other side surface, respectively, of the circuit board 110.

Typically, submersion of an electronic device starts from the lower portion which is positioned close to the ground. Accordingly, as the signal detection terminal 111 and the ground terminal 112 are positioned at the lower edge of the circuit board 110, submersion may quickly be detected.

According to an embodiment, there may be provided a plurality of signal detection terminals 111 which may be disposed at at least two different heights in the vertical direction or vertical positions on the one surface of the circuit board 110. As described above, when there are provided a plurality of signal detection terminals 111, the MCU 130 determines whether each signal detection terminal 111 submerges through the monitoring circuit 120 and monitoring terminal 121 corresponding to each signal detection terminal 111.

FIG. 4B illustrates an embodiment in which two signal detection terminals 111 are positioned at two different heights h1 and h2. Accordingly, if submersion occurs, the MCU 130 may detect submersion from a resistive short circuit between the signal detection terminal 111 which has the height h1 and the ground terminal 112. The MCU 130 may detect that submersion continues from the resistive short circuit between the signal detection terminal 111 which has the height h2 and the ground terminal 112 and, in this case, the MCU 130 may further output an additional alert.

There may be provided more than two signal detection terminals 111 and the signal detection terminals 111 may be placed in different positions in the horizontal direction as well as the vertical direction, on the one side surface of the circuit board 110.

Although FIG. 4A illustrates that the ground terminal 112 is positioned at the same height as the signal detection terminal 111 and FIG. 4B illustrates that the ground terminal 112 is positioned at the same height as the lowest signal detection terminal 111, the present embodiments are not limited thereto.

In other words, when there is only one signal detection terminal 111, the ground terminal 112 may be disposed at the same or lower height than the signal detection terminal 111.

Alternatively, when there are a plurality of signal detection terminals 111, the ground terminal 112 may be disposed at the same or lower height than the lowest signal detection terminal 111.

FIGS. 4C and 4D illustrate an embodiment in which the ground terminal 112 is positioned at height h0 lower than h1. Referring to FIG. 4C, although the ground terminal 112 is positioned at height h0, the height of the signal detection terminal 111 is h1, so that submersion may be detected at the same time as compared with the embodiment of FIG. 4A. Likewise, referring to FIG. 4D, although the ground terminal 112 is positioned at height h0, the heights of the signal detection terminals 111 are h1 and h2, respectively, so that an occurrence of submersion and progress of submersion may be detected at the same time as compared with the embodiment shown in FIG. 4B.

Referring to FIGS. 5A and 5B, according to an embodiment, the circuit board 110 may include a first circuit board 501 and a second circuit board 502. The first circuit board 501 and the second circuit board 502 may be disposed on one side and another side of the same plane.

The first circuit board 501 and the second circuit board 502 may perform the same function. For example, the first circuit board 501 and the second circuit board 502 may independently control the motor for sliding the rack bar. In the normal state in which no submersion occurs, the first circuit board 501 and the second circuit board 502 both may operate or either operates while the other does not operate. When submersion occurs, either the first circuit board 501 or the second circuit board 502 may be cut off from power supply while the other normally functions.

According to an embodiment, at least one portion of the first circuit board 501 may be positioned lower than the second circuit board in the vertical direction, and the signal detection terminal 111 and the ground terminal 112 may be disposed at a lower end of the at least one portion of the first circuit board 501. FIG. 5A illustrates an embodiment in which the entire first circuit board 501 is positioned lower than the second circuit board 502, and FIG. 5B illustrates an embodiment in which only a portion (refer to 501a) of the first circuit board 501 is positioned lower than the second circuit board 502.

As shown in FIGS. 5A and 5B, as a height difference is set between the first circuit board 501 and the second circuit board 502, such an occasion where the first circuit board 501 and the second circuit board 502 simultaneously stop their functions due to submersion may be prevented.

In other words, when submersion occurs, the submersion may be detected from the signal detection terminal 111 and the ground terminal 112 positioned at the lower end of the first circuit board 501 and, instead of cutting off the power supply to the first circuit board 501, the second circuit board 502 may normally function. In this case, upon detecting submersion, the first circuit board 501 may share submersion detection information with the second circuit board 502 to allow the second circuit board 502 to normally function.

Upon detecting submersion from a resistive short circuit in the first circuit board 501, the MCU 130 may stop power supply to the first circuit board 501 and provide a first submersion alarm signal to the second circuit board 502.

The second circuit board 502 receiving the first submersion alarm signal may perform the normal function instead of the first circuit board 501 and output a primary warning message.

If the submersion continues so that a resistive short circuit occurs even in the second circuit board 502, the power supply to the second circuit board 502 may be stopped, and a secondary warning message may be output. To that end, although not shown in FIG. 5, a signal detection terminal and a ground terminal may be disposed on the opposite surfaces of a lower end of the second circuit board 502.

FIGS. 6A and 6B are a side view illustrating a portion of an electronic device according to various exemplary embodiments of the present disclosure.

According to the embodiment of FIG. 6A, the signal detection terminal 111 may be disposed on the first circuit board 501, and the ground terminal 112 may be disposed on the first circuit board 501. If a resistive short circuit occurs between the signal detection terminal 111 and the ground terminal 112, the MCU 130 determines that submersion occurs.

Although FIGS. 6A and 6B illustrate that the entire first circuit board 501 is positioned at a height lower than the second circuit board 502, this is for convenience of illustration and understanding, and only a portion of the first circuit board 501, not the whole, may be positioned at a lower height than the second circuit board 502.

Subsequently, according to an embodiment, as the signal detection terminal 111 and the ground terminal 112 are positioned at a lower end of the first circuit board 501, submersion may quickly be detected if it occurs. To be able to detect submersion before the second circuit board 502 submerges, the signal detection terminal 111 and the ground terminal 112 may be positioned at a height lower of the first circuit board 501, which is lower than the lower end (refer to a dotted line ‘h’ of FIG. 5B) of the second circuit board 502.

Accordingly, it is possible to quickly detect submersion from a resistive short circuit between the signal detection terminal 111 and the ground terminal 112. As the first circuit board 501 shares submersion information (first submersion alarm signal)) with the second circuit board 502, the second circuit board 502 may perform the normal function.

According to an embodiment, a plurality of signal detection terminals 111 may be disposed at at least two different heights in the vertical direction on one side surface of the first circuit board 501. FIG. 6B illustrates an embodiment in which two signal detection terminals 111 are provided and positioned at heights h1 and h2, respectively. If a resistive short circuit occurs at the signal detection terminal 111 having height h1, the MCU 130 may detect the occurrence of submersion and, if a resistive short circuit occurs at the signal detection terminal 111 having height h2, detect that the submersion continues.

According to an embodiment, the signal detection terminal 111 includes a first signal detection terminal 611 disposed on the first circuit board 501 and a second signal detection terminal 621 disposed on the second circuit board 502. The ground terminal 112 may include a first ground terminal 612 disposed on the first circuit board 501 and a second ground terminal 622 disposed on the second circuit board 502. As shown in FIG. 6C, the first signal detection terminal 611 and the first ground terminal 612 may be disposed on two opposite sides, respectively, of the first circuit board 501, and the second signal detection terminal 621 and the second ground terminal 622 may be disposed on two opposite sides, respectively, of the second circuit board 502.

According to an embodiment, the first signal detection terminal 611 and the first ground terminal 612 may be positioned at a lower end of the first circuit board 501, and the second signal detection terminal 621 and the second ground terminal 622 may be positioned at a lower end of the second circuit board 502. Accordingly, it is possible to quickly detect submersion of the first circuit board 501 from a resistive short circuit between the first signal detection terminal 611 and the first ground terminal 612 to cut off the power supply to the first circuit board 501 while allowing the second circuit board 502 to perform the normal function. The MCU 130 may detect an occurrence of submersion from a resistive short circuit between the second signal detection terminal 621 and the second ground terminal 622 and take a subsequent measure, such as outputting a secondary warning message.

As illustrated in FIG. 6D showing another embodiment, a plurality of first signal detection terminals 611 may be disposed at at least two different heights in the vertical direction on one side surface of the first circuit board 501. Accordingly, if a resistive short circuit occurs at the signal detection terminal 611 having height h1, the MCU 130 may detect the occurrence of submersion and output a primary warning message and, if a resistive short circuit occurs at the signal detection terminal 611 having height h2, the MCU 130 may detect that the submersion continues and output a secondary warning message. If a resistive short circuit occurs at the signal detection terminal 621 of the second circuit board 502, the MCU 130 may output a third warning message.

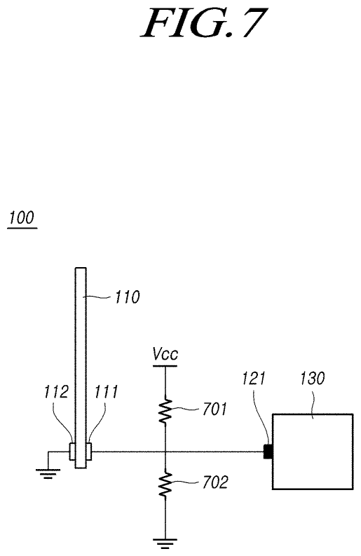

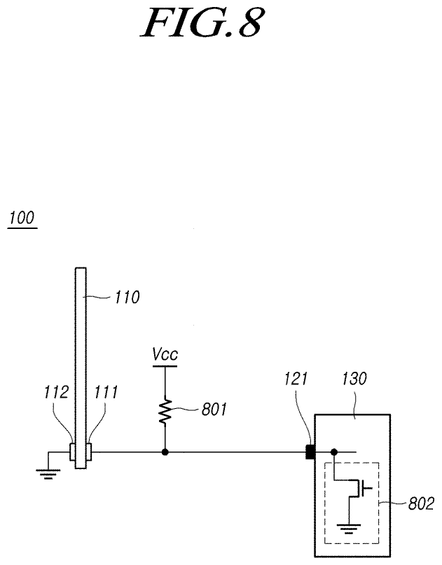

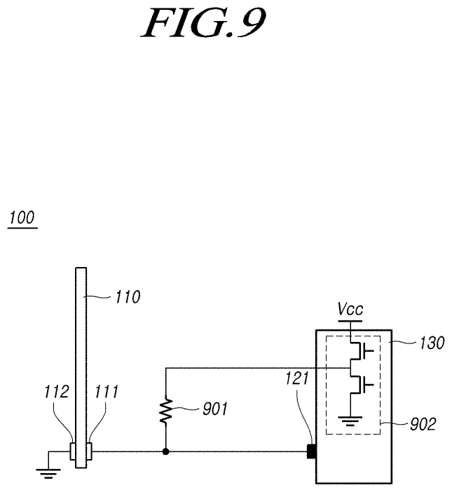

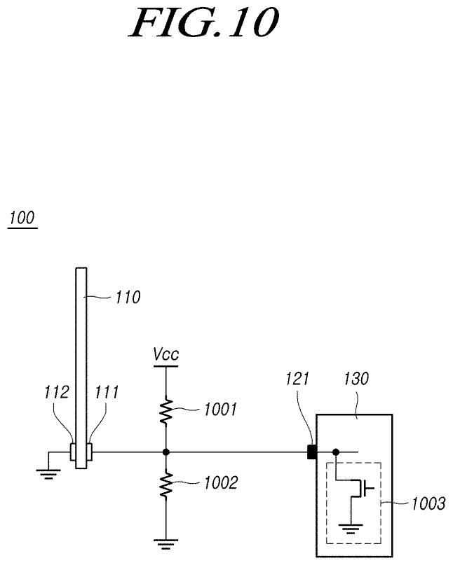

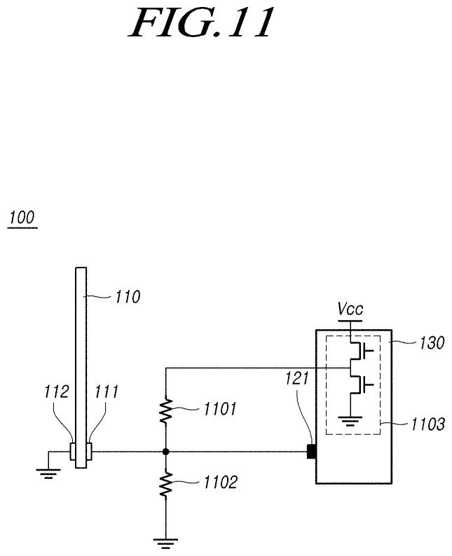

FIG. 7 is a circuit diagram illustrating an electronic device according to one exemplary embodiment of the present disclosure. FIG. 8 is a circuit diagram illustrating an electronic device according to one exemplary embodiment of the present disclosure. FIG. 9 is a circuit diagram illustrating an electronic device according to one exemplary embodiment of the present disclosure. FIG. 10 is a circuit diagram illustrating an electronic device according to one exemplary embodiment of the present disclosure. FIG. 11 is a circuit diagram illustrating an electronic device according to one exemplary embodiment of the present disclosure.

Although the description is made of an embodiment in which the ground terminal 112 is disposed on the other side surface of the circuit board 110, it should be noted that it is so done merely for convenience of description. In other words, in the embodiment shown in FIGS. 7 to 11, rather than the ground terminal 112 being disposed on the other side surface of the circuit board 110, the housing receiving the circuit board 110 may be connected to the ground, or the ground terminal 112 may be electrically connected to the grounded housing.

Referring to FIG. 7, the electronic device 100 according to one exemplary embodiment of the present disclosure may further include a first resistor 701 connected with the constant power source Vcc between the signal detection terminal 111 and the monitoring terminal 121 and a second resistor 702 connected with the ground between the signal detection terminal 111 and the monitoring terminal 121. In other words, the first resistor 701 and the second resistor 702 are connected between the constant power source Vcc and the ground, and the monitoring terminal 121 is connected between the first resistor 701 and the second resistor 702.

Therefore, the normal state voltage detected by the MCU 130 from the monitoring terminal 121 in the normal state where submersion does not occur is determined by the constant power source Vcc, the first resistor 701, and the second resistor 702. In other words, the normal state voltage is determined by the constant power source Vcc and the resistance ratio of the first resistor 701 and the second resistor 702. For example, when the first resistor 701 and the second resistor 702 have the same resistance, the normal state voltage at the monitoring terminal 121 is half that of the constant power source Vcc. The MCU 130 determines whether there is submersion by comparing the monitored voltage at the monitoring terminal 121 with the normal state voltage.

Since the normal state voltage which is the voltage at the monitoring terminal 121 in the normal state maintains a predetermined voltage level by the constant power source Vcc, the first resistor 701, and the second resistor 702, the MCU 130 may distinguish between a short circuit due to, e.g., failure in the monitoring circuit 120 and a short circuit due to submersion. In other words, when the voltage at the monitoring terminal 121 is fixed to the ground, the MCU 130 may determine that there is a failure in the monitoring circuit 120 and, when the voltage drop relative to the normal state voltage maintains a specific threshold voltage range for a specific threshold time or longer, the MCU 130 may determine that there is submersion.

According to the embodiment shown in FIG. 7, the normal state voltage is determined using resistors. Thus, it is possible to implement the circuit in a simplified manner. Any normal state voltage may be set so that it is possible to intuitively detect submersion. For example, when the constant power source is 5V and the first resistor 701 and the second resistor 702 are 200Ω and 300Ω, respectively, the normal state voltage is determined to be 3V. When the voltage at the monitoring terminal 121 remains the normal state voltage, the MCU 130 determines that it is in the normal state where no submersion occurs. When the voltage at the monitoring terminal 121 drops from 3V to the ground and is fixed to the ground, the MCU 130 may determine that there is a failure in the monitoring circuit 120 and, when the voltage drops from 3V by 10%, i.e., to 2.7V or less and the dropped voltage is maintained 100 ms or longer, the MCU 130 may determine that there is submersion.

Referring to FIG. 8, the electronic device 100 according to one exemplary embodiment of the present disclosure may further include a resistor 801 connected with the constant power source Vcc between the signal detection terminal 111 and the monitoring terminal 121, and the MCU 130 may include a switching circuit 802 for shorting or opening the monitoring terminal 121 and the ground. In other words, when the monitoring terminal 121 and the ground are shorted by the switching circuit 802, the voltage at the monitoring terminal 121 has the ground voltage and, when opened, the voltage at the monitoring terminal 121 has the normal state voltage which is set by the constant power source Vcc and the resistor 801.

The MCU 130 may determine whether there is submersion from a change in voltage at the monitoring terminal 121 due to the on/off of the switching circuit 802.

In the normal state, if the monitoring terminal 121 and the ground are shorted, the voltage at the monitoring terminal 121 has the ground voltage (i.e., 0V) and, if opened (i.e., not shorted), the voltage at the monitoring terminal 121 has the normal state voltage set by the constant power source Vcc and the resistor 801. In this case, the MCU 130 may determine whether there is submersion from a change in voltage at the monitoring terminal 121 according to a gate signal input to the switching circuit 802. For example, when a phase difference between the gate signal and the voltage at the monitoring terminal 121 falls off a specific threshold range, and/or when the monitoring voltage at the time where the monitoring terminal 121 and the ground are shorted falls off a specific threshold range relative to the normal state voltage set by the constant power source Vcc and the resistor 801, the MCU 130 may determine that there is submersion.

According to an embodiment, the MCU 130 may output a pulse signal for turning on/off the switching circuit 802. In other words, the switching circuit 802 is periodically turned on/off by the pulse signal, so that the voltage at the monitoring terminal 121 varies between the ground voltage and the normal state voltage. The MCU 130 may determine whether there is submersion from whether the voltage at the monitoring terminal 121 varies according to the pulse signal input to the switching circuit 802 and the voltage.

In the normal state, since the voltage at the monitoring terminal 121 when the monitoring terminal 121 and the ground are opened maintains a predetermined voltage level by the constant power source Vcc and the resistor 801, the MCU 130 may distinguish between a short circuit due to, e.g., failure in the monitoring circuit 120 and a short circuit due to submersion. In other words, when the voltage at the monitoring terminal 121 is fixed to the ground despite the on/off of the switching circuit 802, the MCU 130 may determine that there is a failure in the monitoring circuit 120 and, when the voltage drop relative to the normal state voltage maintains a specific threshold voltage range for a specific threshold time or longer, determines that there is submersion.

According to the embodiment shown in FIG. 8, since the response which is a voltage variation when the switching circuit 802 is turned on/off steadily occurs, robustness to noise is achieved. For example, the constant power source Vcc may be 5V, the normal state voltage may be 3V, and the switching circuit 802 may be turned on/off every 1 s. When the voltage at the monitoring terminal 121 is varied to 3V or the ground voltage every is by the on/off of the switching circuit 802, the MCU 130 determines that there is no submersion. When the voltage at the monitoring terminal 121 drops from 3V to the ground voltage despite the on/off of the switching circuit 802, the MCU 130 may determine that the monitoring circuit 120 has a failure and, when the voltage is varied and dropped from 3V by 10% or more, i.e., to 2.7V or less and the dropped voltage is maintained 100 ms or longer and/or when a response error of 0.1 s which is 10% of 1 s occurs, the MCU 130 may determine that there is submersion.

Referring to FIG. 9, the electronic device 100 according to one exemplary embodiment of the present disclosure may further include a resistor 901 having an end connected between the signal detection terminal 111 and the monitoring terminal 121. The MCU 130 may include a switching circuit 902 for shorting the resistor 901 and the constant power source Vcc and opening the other end of the resistor 901 and the ground or for opening the other end of the resistor 901 and the constant power source Vcc and shorting the other end of the resistor 901 and the ground. In other words, the other end of the resistor 901 is connected to either the constant power source Vcc or the ground by the switching circuit 902. When the other end of the resistor 901 is connected to the constant power source, the voltage at the monitoring terminal 121 has the normal voltage level set by the constant power source Vcc and the resistor 901 and, when the other end of the resistor 901 is connected with the ground, the voltage at the monitoring terminal 121 has the ground voltage.

The MCU 130 may determine whether there is submersion from a change in voltage at the monitoring terminal 121 due to the on/off of the switching circuit 902. In the normal state, if the other end of the resistor 901 is connected with the ground, the voltage at the monitoring terminal 121 has the ground voltage and, if the other end of the resistor 901 is connected with the constant power source Vcc, the voltage at the monitoring terminal 121 has the normal voltage level set by the constant power source Vcc and the resistor 901. In this case, the MCU 130 may determine whether there is submersion from a change in voltage at the monitoring terminal 121 according to a gate signal input to the switching circuit 902. For example, when a phase difference between the gate signal and the voltage at the monitoring terminal 121 falls off a specific threshold range, and/or when the monitoring voltage at the time where the monitoring terminal 121 and the ground are shorted falls off a specific threshold range relative to the normal voltage level set by the constant power source Vcc and the resistor 901, the MCU 130 may determine that there is submersion.

According to an embodiment, the MCU 130 may output a pulse signal for turning on/off the switching circuit 902. In other words, the switching circuit 902 is periodically turned on/off by the pulse signal, so that the voltage at the monitoring terminal 121 varies between the ground voltage and the normal voltage level. The MCU 130 may determine whether there is submersion from whether the voltage at the monitoring terminal 121 varies according to the pulse signal input to the switching circuit 902 and the voltage level.

In the normal state, since the voltage at the monitoring terminal 121 when the other end of the resistor 901 is connected with the constant power source Vcc maintains a predetermined voltage level by the constant power source Vcc and the resistor 901, the MCU 130 may distinguish between a short circuit due to, e.g., failure in the monitoring circuit 120 and a short circuit due to submersion. In other words, when the voltage at the monitoring terminal 121 is fixed to the ground despite the on/off of the switching circuit 902, the MCU 130 may determine that there is a failure in the monitoring circuit 120 and, when the voltage drop relative to the normal voltage maintains a specific threshold voltage range for a specific threshold time or longer, determines that there is submersion.

According to the embodiment shown in FIG. 9, since the response which is a voltage variation when the switching circuit 902 is turned on/off steadily occurs, it is relatively robust to noise. For example, the constant power source Vcc may be 5V, the normal state voltage may be 3V, and the switching circuit 902 may be turned on/off every 1 s. When the voltage at the monitoring terminal 121 is varied to 3V or the ground voltage every is by the on/off of the switching circuit 902, the MCU 130 determines that there is no submersion. When the voltage at the monitoring terminal 121 drops from 3V to the ground voltage despite the on/off of the switching circuit 902, the MCU 130 may determine that the monitoring circuit 120 has a failure and, when the voltage is varied and dropped from 3V by 10% or more, i.e., to 2.7V or less and the dropped voltage is maintained 100 ms or longer and/or when a response error of 0.1 s which is 10% of 1 s occurs, the MCU 130 may determine that there is submersion.

Referring to FIG. 10, the electronic device 100 according to one exemplary embodiment of the present disclosure may further include a third resistor 1001 connected with the constant power source Vcc between the signal detection terminal 111 and the monitoring terminal 121 and a fourth resistor 1002 connected with the ground between the signal detection terminal 111 and the monitoring terminal 121. The MCU 130 may include a switching circuit 1003 for shorting or opening the monitoring terminal 121 and the ground. In other words, the third resistor 1001 and the fourth resistor 1002 are connected between the constant power source Vcc and the ground, and the monitoring terminal 121 is connected between the third resistor 1001 and the fourth resistor 1002. When the monitoring terminal 121 and the ground are shorted by the switching circuit 1003, the voltage at the monitoring terminal 121 has the ground voltage and, when opened, the voltage at the monitoring terminal 121 has the normal state voltage which is set by the constant power source Vcc, the third resistor 1001, and the fourth resistor 1002.

The MCU 130 may determine whether there is submersion from a change in voltage at the monitoring terminal 121 due to the on/off of the switching circuit 1003. In the normal state, if the monitoring terminal 121 and the ground are shorted, the voltage at the monitoring terminal 121 has the ground voltage and, if opened (i.e., not shorted), the voltage at the monitoring terminal 121 has the normal state voltage set by the constant power source Vcc, the third resistor 1001, and the fourth resistor 1002. In this case, the MCU 130 may determine whether there is submersion from a change in voltage at the monitoring terminal 121 according to a gate signal input to the switching circuit 1003. For example, when a phase difference between the gate signal and the voltage at the monitoring terminal 121 falls off a specific threshold range, and/or when the monitoring voltage at the time where the monitoring terminal 121 and the ground are shorted falls off a specific threshold range relative to the normal state voltage set by the constant power source Vcc, the third resistor 1001, and the fourth resistor 1002, the MCU 130 may determine that there is submersion.

According to an embodiment, the MCU 130 may output a pulse signal for turning on/off the switching circuit 1003. In other words, the switching circuit 1003 is periodically turned on/off by the pulse signal, so that the voltage at the monitoring terminal 121 varies between the ground voltage and the normal state voltage. The MCU 130 may determine whether there is submersion from whether the voltage at the monitoring terminal 121 varies according to the pulse signal input to the switching circuit 1003 and the voltage level.

In the normal state, since the voltage at the monitoring terminal 121 when the monitoring terminal 121 and the ground are opened maintains a predetermined voltage level by the constant power source Vcc, the third resistor 1001, and the fourth resistor 1002, the MCU 130 may distinguish between a short circuit due to, e.g., failure in the monitoring circuit 120 and a short circuit due to submersion. In other words, when the voltage at the monitoring terminal 121 is fixed to the ground despite the on/off of the switching circuit 1003, the MCU 130 may determine that there is a failure in the monitoring circuit 120 and, when the voltage drop relative to the normal state voltage maintains a specific threshold voltage range for a specific threshold time or longer, determines that there is submersion.

According to the embodiment shown in FIG. 10, since the normal state voltage is determined using resistors, any normal state voltage may be set so that submersion may be intuitively detected. Since the response which is a voltage change when the switching circuit 1003 is turned on/off steadily occurs, robustness to noise is achieved. For example, when the constant source is 5V and the third resistor 1001 and the fourth resistor 1002 are 200Ω and 300Ω, respectively, the normal state voltage is determined to be 3V, and the switching circuit 1003 may be turned on/off every 1 s. When the voltage at the monitoring terminal 121 is varied to 3V or the ground voltage every is by the on/off of the switching circuit 1003, the MCU 130 determines that there is no submersion. When the voltage at the monitoring terminal 121 drops from 3V to the ground voltage despite the on/off of the switching circuit 1003, the MCU 130 may determine that the monitoring circuit 120 has a failure. Further, when the voltage is varied and dropped from 3V by 10% or more, i.e., to 2.7V or less and the dropped voltage is maintained 100 ms or longer, and/or when a response error of 0.1 s which is 10% of 1 s occurs, the MCU 130 may determine that there is submersion.

Referring to FIG. 11, the electronic device 100 according to one exemplary embodiment of the present disclosure may further include a fifth resistor 1101 having an end connected between the signal detection terminal 111 and the monitoring terminal 121 and a sixth resistor 1102 connected with the ground between the signal detection terminal 111 and the monitoring terminal 121. The MCU 130 may include a switching circuit 1103 for shorting the other end of the fifth resistor 1101 and the constant power source Vcc and opening the other end of the fifth resistor 1101 and the ground or for opening the other end of the fifth resistor 1101 and the constant power source and shorting the other end of the fifth resistor 1101 and the ground. In other words, the fifth resistor 1101 and the sixth resistor 1102 are connected between the constant power source Vcc and the ground, and the monitoring terminal 121 is connected between the fifth resistor 1101 and the sixth resistor 1102. The other end of the fifth resistor 1101 is connected to either the constant power source Vcc or the ground by the switching circuit 1103. When the other end of the fifth resistor 1101 is connected to the constant power source, the voltage at the monitoring terminal 121 has the normal state voltage set by the constant power source Vcc, the fifth resistor 1101, and the sixth resistor 1102 and, when the other end of the fifth resistor 1101 is connected with the ground, the voltage at the monitoring terminal 121 has the ground voltage.

The MCU 130 may determine whether there is submersion from a change in voltage at the monitoring terminal 121 due to the on/off of the switching circuit 1103. In the normal state, if the other end of the fifth resistor 1101 is connected with the ground, the voltage at the monitoring terminal 121 has the ground voltage and, if the other end of the fifth resistor 1101 is connected with the constant power source Vcc, the voltage at the monitoring terminal 121 has the normal state voltage set by the constant power source Vcc, the fifth resistor 1101, and the sixth resistor 1102. In this case, the MCU 130 may determine whether there is submersion from a change in voltage at the monitoring terminal 121 according to a gate signal input to the switching circuit 1103. For example, when a phase difference between the gate signal and the voltage at the monitoring terminal 121 falls off a specific threshold range, and/or when the monitoring voltage at the time where the monitoring terminal 121 and the ground are shorted falls off a specific threshold range relative to the normal state voltage set by the constant power source Vcc, the fifth resistor 1101, and the sixth resistor 1102, the MCU 130 may determine that there is submersion.

According to an embodiment, the MCU 130 may output a pulse signal for turning on/off the switching circuit 1103. In other words, the switching circuit 1103 is periodically turned on/off by the pulse signal, so that the voltage at the monitoring terminal 121 varies between the ground voltage and the normal state voltage. The MCU 130 may determine whether there is submersion from whether the voltage at the monitoring terminal 121 varies according to the pulse signal input to the switching circuit 1103 and the voltage level.

In the normal state, since the voltage at the monitoring terminal 121 when the other end of the fifth resistor 1101 is connected with the constant power source Vcc maintains a predetermined voltage level by the constant power source Vcc, the fifth resistor 1101, and the sixth resistor 1102, the MCU 130 may distinguish between a short circuit due to, e.g., failure in the monitoring circuit 120 and a short circuit due to submersion. In other words, when the voltage at the monitoring terminal 121 is fixed to the ground despite the on/off of the switching circuit 1103, the MCU 130 may determine that there is a failure in the monitoring circuit 120 and, when the voltage drop relative to the normal state voltage maintains a specific threshold voltage range for a specific threshold time or longer, determines that there is submersion.

According to the embodiment shown in FIG. 11, since the normal state voltage is determined using resistors, any normal state voltage may be set so that submersion may be intuitively detected. Since the response which is a voltage change when the switching circuit 1103 is turned on/off steadily occurs, robustness to noise is achieved. For example, when the constant source is 5V and the fifth resistor 1101 and the sixth resistor 1102 are 200Ω and 300Ω, respectively, the normal state voltage is determined to be 3V, and the switching circuit 1103 may be turned on/off every 1 s. When the voltage at the monitoring terminal 121 is varied to 3V or the ground voltage every is by the on/off of the switching circuit 1103, the MCU 130 determines that there is no submersion. When the voltage at the monitoring terminal 121 drops from 3V to the ground voltage despite the on/off of the switching circuit 1103, the MCU 130 may determine that the monitoring circuit 120 has a failure and, when the voltage is varied and dropped from 3V by 10% or more, i.e., to 2.7V or less and the dropped voltage is maintained 100 ms or longer and/or when a response error of 0.1 s which is 10% of 1 s occurs, the MCU 130 may determine that there is submersion.

Hereinafter, a method for operating an electronic device according to one exemplary embodiment of the present disclosure is described. According to an embodiment, a method for operating an electronic device including a circuit board having a signal detection terminal disposed on a first surface thereof and a ground terminal disposed on a second surface thereof and extending vertically so that the first surface and the second surface face each other in a horizontal direction, a monitoring terminal connected with the signal detection terminal, and an MCU connected with the monitoring terminal comprises monitoring a voltage at the monitoring terminal, comparing the voltage at the monitoring terminal with a normal state voltage, and determining whether there is submersion from the comparison.

According to an embodiment, the electronic device further includes a first resistor connected with a constant power source between the signal detection terminal and the monitoring terminal and a second resistor connected with a ground between the signal detection terminal and the monitoring terminal. The normal state voltage is set by the constant power source, the first resistor and the second resistor.

According to an embodiment, the electronic device further includes a resistor connected with a constant power source between the signal detection terminal and the monitoring terminal, wherein the MCU includes a switching circuit for shorting or opening the monitoring terminal and a ground. The normal state voltage is the ground when the monitoring terminal is connected to the ground by the switching circuit and is set by the constant power source and the resistor when the monitoring terminal is shorted from the ground.

According to an embodiment, the electronic device further includes a resistor having a first end connected between the signal detection terminal and the monitoring terminal. The MCU includes a switching circuit for shorting a second end of the resistor and a constant power source and opening the second end of the resistor and a ground or for opening the second end of the resistor and the constant power source and shorting the second end of the resistor and the ground. The normal state voltage is the ground when the second end of the resistor is connected to the ground by the switching circuit and is set by the constant power source and the resistor when the second end of the resistor is connected to the constant power source.

According to an embodiment, the electronic device further includes a third resistor connected with a constant power source between the signal detection terminal and the monitoring terminal and a fourth resistor connected with a ground between the signal detection terminal and the monitoring terminal, wherein the MCU includes a switching circuit for shorting or opening the monitoring terminal and the ground. The normal state voltage is the ground when the monitoring terminal is connected to the ground by the switching circuit and is set by the constant power source, the third resistor, and the fourth resistor when the monitoring terminal is shorted from the ground.

According to an embodiment, the electronic device further includes a fifth resistor having a first end connected between the signal detection terminal and the monitoring terminal and a sixth resistor connected with a ground between the signal detection terminal and the monitoring terminal. The MCU includes a switching circuit for shorting a second end of the fifth resistor and a constant power source and opening the second end of the resistor and a ground or for opening the second end of the resistor and the constant power source and shorting the second end of the resistor and the ground. The normal state voltage is the ground when the second end of the fifth resistor is connected to the ground by the switching circuit and is set by the constant power source, the fifth resistor, and the sixth resistor when the second end of the fifth resistor is connected to the constant power source.

By the so-shaped electronic device and the method for operating the electronic device, it is possible to prevent hypersensitivity-induced misdetection due to condensation or dew. It is also possible to stepwise respond to submersion and determine whether the monitoring circuit normally operates to precisely detect submersion.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure. Thus, the scope of the disclosure is not limited to the embodiments shown, but is to be accorded the widest scope consistent with the claims. The scope of protection of the disclosure should be construed based on the following claims, and all technical ideas within the scope of equivalents thereof should be construed as being included within the scope of the disclosure.

What is claimed is:

1. An electronic device, comprising:
a circuit board having a signal detection terminal disposed on a first surface thereof and a ground terminal disposed on a second surface thereof and extending vertically so that the first surface and the second surface face each other in a horizontal direction;
a monitoring terminal connected with the signal detection terminal; and
a microcontroller unit (MCU) determining whether there is submersion by monitoring a voltage at the monitoring terminal.

2. The electronic device of claim 1, wherein the signal detection terminal and the ground terminal are positioned at a lower end of the circuit board.

3. The electronic device of claim 1, wherein the signal detection terminal is provided in plural and positioned on the first surface of the circuit board at at least two different heights in a vertical direction.

4. The electronic device of claim 1, wherein the circuit board includes a first circuit board disposed on a first side and a second circuit board disposed on a second side.

5. The electronic device of claim 4, wherein at least one portion of the first circuit board is positioned lower than the second circuit board in a vertical direction, and wherein the signal detection terminal and the ground terminal are disposed at a lower end of the at least one portion of the first circuit board.

6. The electronic device of claim 4, wherein the signal detection terminal is disposed on the first circuit board, and the ground terminal is disposed on the first circuit board.

7. The electronic device of claim 6, wherein the signal detection terminal and the ground terminal are positioned at a lower end of the first circuit board.

8. The electronic device of claim 6, wherein the signal detection terminal is provided in plural and positioned on a first surface of the first circuit board at at least two different heights in a vertical direction.

9. The electronic device of claim 4, wherein the signal detection terminal includes a first signal detection terminal disposed on the first circuit board and a second signal detection terminal disposed on the second circuit board, and the ground terminal includes a first ground terminal disposed on the first circuit board and a second ground terminal disposed on the second circuit board.

10. The electronic device of claim 9, wherein the first signal detection terminal and the first ground terminal are positioned at a lower end of the first circuit board, and the second signal detection terminal and the second ground terminal are positioned at a lower end of the second circuit board.

11. The electronic device of claim 9, wherein the first signal detection terminal is provided in plural and positioned on a first surface of the first circuit board at at least two different heights in a vertical direction.

12. The electronic device of claim 1, further comprising a first resistor connected with a constant power source between the signal detection terminal and the monitoring terminal, and a second resistor connected with a ground between the signal detection terminal and the monitoring terminal.

13. The electronic device of claim 12, wherein the MCU determines whether there is submersion by comparing the voltage at the monitoring terminal with a normal state voltage determined by the constant power source, the first resistor, and the second resistor.

14. The electronic device of claim 1, further comprising a resistor connected with a constant power source between the signal detection terminal and the monitoring terminal, wherein the MCU includes a switching circuit for shorting or opening the monitoring terminal and a ground.

15. The electronic device of claim 1, further comprising a resistor having a first end connected between the signal detection terminal and the monitoring terminal,
wherein the MCU includes a switching circuit for shorting a second end of the resistor and a constant power source and opening the second end of the resistor and a ground, or for opening the second end of the resistor and the constant power source and shorting the second end of the resistor and the ground.

16. The electronic device of claim 1, further comprising a third resistor connected with a constant power source between the signal detection terminal and the monitoring terminal and a fourth resistor connected with a ground between the signal detection terminal and the monitoring terminal, wherein the MCU includes a switching circuit for shorting or opening the monitoring terminal and the ground.

17. The electronic device of claim 1, further comprising a fifth resistor having a first end connected between the signal detection terminal and the monitoring terminal and a sixth resistor connected with a ground between the signal detection terminal and the monitoring terminal,
wherein the MCU includes a switching circuit for shorting a second end of the fifth resistor and a constant power source and opening the second end of the resistor and a ground, or for opening the second end of the fifth resistor and the constant power source and shorting the second end of the resistor and the ground.

18. The electronic device of claim 14, wherein the MCU determines whether there is submersion from a change in the voltage at the monitoring terminal according to turning on or off of the switching circuit.

19. The electronic device of claim 14, wherein the MCU outputs a pulse signal for turning on or off the switching circuit.

20. The electronic device of claim 1, wherein the ground terminal is positioned at a lower height than the signal detection terminal.

21. The electronic device of claim 1, wherein the ground terminal is positioned at a same height as the signal detection terminal.

22. An electronic device, comprising:
a circuit board having a signal detection terminal disposed on a first surface thereof and extending vertically so that the first surface and a second surface face each other in a horizontal direction;
a housing receiving the circuit board and connected to a ground;
a monitoring terminal connected with the signal detection terminal; and
a microcontroller unit (MCU) determining submersion by monitoring a voltage of the monitoring terminal.

23. The electronic device of claim 22, wherein the second surface of the circuit board is free of a ground terminal.

24. The electronic device of claim 23, wherein the MCU detects the submersion based on a voltage drop at the monitoring terminal due to a resistive short circuit between the housing and the signal detection terminal.

25. A method for operating an electronic device including a circuit board having a signal detection terminal disposed on a first surface thereof and a ground terminal disposed on a second surface thereof and extending vertically so that the first surface and the second surface face each other in a horizontal direction, a monitoring terminal connected with the signal detection terminal, and a microcontroller unit (MCU) connected with the monitoring terminal, the method comprising:
monitoring a voltage at the monitoring terminal;
comparing the voltage at the monitoring terminal with a normal state voltage; and
determining whether there is submersion from the comparison.

26. The method of claim 25, wherein the electronic device further includes a first resistor connected with a constant power source between the signal detection terminal and the monitoring terminal and a second resistor connected with a ground between the signal detection terminal and the monitoring terminal, wherein the normal state voltage is set by the constant power source, the first resistor and the second resistor.

27. The method of claim 25, wherein the electronic device further includes a resistor connected with a constant power source between the signal detection terminal and the monitoring terminal, wherein the MCU includes a switching circuit for shorting or opening the monitoring terminal and a ground, and
wherein the normal state voltage is the ground when the monitoring terminal is connected to the ground by the switching circuit and is set by the constant power source and the resistor when the monitoring terminal is shorted from the ground by the switching circuit.

28. The method of claim 25, wherein the electronic device further includes a resistor having a first end connected between the signal detection terminal and the monitoring terminal, wherein the MCU includes a switching circuit for shorting a second end of the resistor and a constant power source and opening the second end of the resistor and a ground, or for opening the second end of the resistor and the constant power source and shorting the second end of the resistor and the ground,
wherein the normal state voltage is the ground when the second end of the resistor is connected to the ground by the switching circuit and is set by the constant power source and the resistor when the second end of the resistor is connected to the constant power source by the switching circuit.

29. The method of claim 25, wherein the electronic device further includes a third resistor connected with a constant power source between the signal detection terminal and the monitoring terminal and a fourth resistor connected with a ground between the signal detection terminal and the monitoring terminal, wherein the MCU includes a switching circuit for shorting or opening the monitoring terminal and the ground, and
wherein the normal state voltage is the ground when the monitoring terminal is connected to the ground by the switching circuit and is set by the constant power source, the third resistor, and the fourth resistor when the monitoring terminal is shorted from the ground by the switching circuit.

30. The method of claim 25, wherein the electronic device further includes a fifth resistor having a first end connected between the signal detection terminal and the monitoring terminal and a sixth resistor connected with a ground between the signal detection terminal and the monitoring terminal,
wherein the MCU includes a switching circuit for shorting a second end of the fifth resistor and a constant power source and opening the second end of the resistor and a ground, or for opening the second end of the resistor and the constant power source and shorting the second end of the resistor and the ground,
wherein the normal state voltage is the ground when the second end of the fifth resistor is connected to the ground by the switching circuit and is set by the constant power source, the fifth resistor, and the sixth resistor when the second end of the fifth resistor is connected to the constant power source by the switching circuit.

31. A steer-by-wire steering device including the electronic device of claim 1.

32. A steer-by-wire steering device including the electronic device of claim 22.

33. A vehicle with a power-assisted steering system or a steer-by-wire system, comprising:
a motor for sliding a rack bar in a steering system of the vehicle, the motor being coupled to a rack housing and positioned at a bottom of the vehicle; and
the electronic device of claim 1, wherein the electronic device is coupled to the motor to control the motor to assist a driver in steering in the power-assisted steering system or to control the motor in response to the driver's steering in the steer-by-wire system.

34. A vehicle with a power-assisted steering system or a steer-by-wire system, comprising:
a motor for sliding a rack bar in a steering system of the vehicle, the motor being coupled to a rack housing and positioned at a bottom of the vehicle; and
the electronic device of claim 22, wherein the electronic device is coupled to the motor to control the motor to assist a driver in steering in the power-assisted steering system or to control the motor in response to the driver's steering in the steer-by-wire system.
